(19) United States
(12) Patent Application Publication
(10) Pub. No.: US 2024/0387304 A1
(43) Pub. Date: Nov. 21, 2024

(54) Integrated Circuit Packages and Methods

(71) Applicant: Taiwan Semiconductor Manufacturing Co., Ltd., Hsinchu (TW)

(72) Inventors: Bo-Huan Hsin, Taichung City (TW); Ying-Han Chiou, Tainan City (TW)

(21) Appl. No.: 18/318,985

(22) Filed: May 17, 2023

(51) Int. Cl. H01L 23/10; H01L 21/56; H01L 21/8234; H01L 23/00; H01L 23/29; H01L 23/31; H01L 23/528; H01L 25/10

(52) U.S. Cl. CPC H01L 23/10; H01L 21/565; H01L 21/823475; H01L 23/293; H01L 23/3128; H01L 23/5283; H01L 24/08; H01L 25/105; H01L 2224/08145; H01L 2924/10156

(57) ABSTRACT

A semiconductor structure with a protective ring and the method of forming the same are provided. The semiconductor structure may comprise an integrated circuit die and an encapsulant encircling the integrated circuit die in a top down view. The integrated circuit die may comprise a substrate having an electrical device, an interconnect structure on the substrate and electrically coupled to the electrical device, a seal ring in the interconnect structure and encircling the electrical device in the top down view, and a protective ring at least partially embedded in the substrate. The protective ring may encircle the seal ring in a top down view and may comprise a material different from a material of the substrate.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6A, 6B, and 6C illustrate various views of intermediate steps during a process for forming an integrated circuit die, in accordance with some embodiments.

FIGS. 7A, 7B, and 7C illustrate various views of an integrated circuit die, in accordance with some embodiments.

FIGS. 8, 9, 10, 11, 12, 13, 14, 15, 16A, and 16B illustrate various views of intermediate steps during a process for forming an integrated circuit package, in accordance with some embodiments.

FIGS. 17, 18, 19A, 19B, and 19C illustrate various views of various integrated circuit packages, in accordance with some embodiments.

FIGS. 20, 21A, 21B, and 21C illustrate various views of various integrated circuit dies, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an integrated circuit package comprises an integrated circuit die with an enlarged size that may include one or more protective rings disposed between, for example, a seal ring and an edge of the integrated circuit die. The enlarged size of the integrated circuit die may reduce cracks in an encapsulant around the integrated circuit die and the one or more protective rings may reduce cracks in the integrated circuit die. As a result, the yield and the reliability of the integrated circuit package may be improved. The one or more protective rings may be continuous or fragmented in a top-down view, and may be disposed in the substrate and/or extend through one or more of the dielectric layers on the substrate.

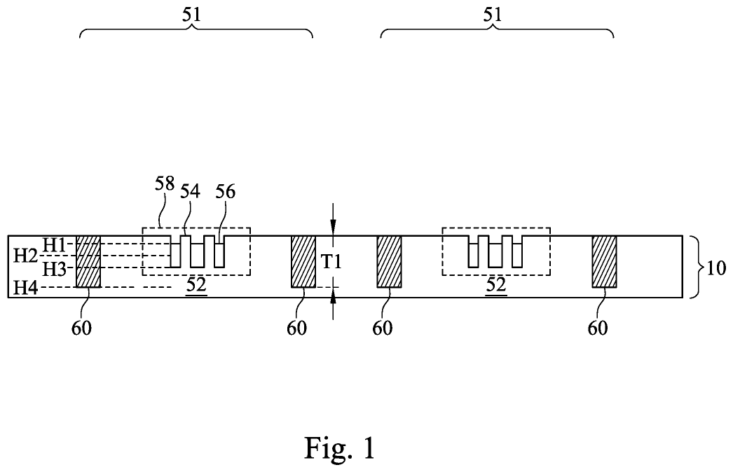

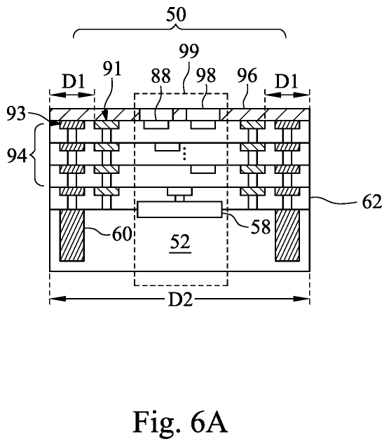

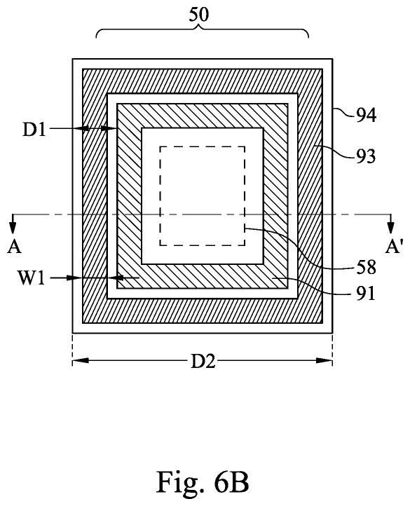

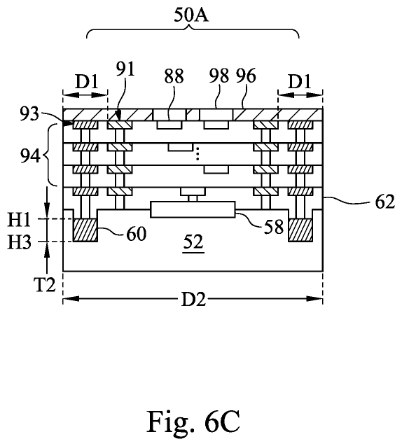

FIGS. 1 through 6C are views of intermediate stages in the manufacturing of integrated circuit dies 50, in accordance with some embodiments. FIG. 6B is a top-down view. FIGS. 1, 2, 3, 4, 5, 6A, and 6C are cross-sectional views shown along reference cross-section A-A′ in the top-down view of FIG. 6B.

In FIG. 1, a cross-sectional view of a wafer 10 is illustrated. The wafer 10 comprises die regions 51, which may be subsequently formed and singulated into individual integrated circuit dies. Each die region 51 may comprise a device region 58. Electrical devices, including active devices (e.g., transistors, diodes, etc.) and/or passive devices (e.g., capacitors, resistors, etc.) may be subsequently formed in the device regions 58. The wafer 10 comprises a semiconductor substrate 52, such as doped or undoped silicon, germanium, a compound semiconductor (e.g., silicon carbide, gallium arsenic, gallium phosphide, indium phosphide, indium arsenide, indium antimonide), or an alloy semiconductor (e.g., SiGe, GaAsP, AlInAs, AlGaAs, GaInAs, GaInP, GaInAsP). Other substrates, such as multi-layered, gradient substrates, semiconductor-on-insulator (SOI) substrate, may also be used. The semiconductor substrate 52 may have an active surface (e.g., the surface facing upwards in FIG. 1), sometimes called a front side, and an inactive surface (e.g., the surface facing downwards in FIG. 1), sometimes called a back side. The device region 58 may be disposed on the active surface of the semiconductor substrate 52.

In the embodiments where transistors, such as fin field-effect transistor (FinFET), nanowire FET, complementary FET (CFET), or the like, are disposed in the device regions 58, fins 54 and shallow trench isolation (STI) regions 56 are formed in device regions 58. The fins 54 may be semiconductor strips, which may be formed in the semiconductor substrate 52 by forming a patterned mask on the semiconductor substrate 52 and etching trenches in the semiconductor substrate 52 through openings of the patterned mask. The patterned mask may be deposited then patterned using one or more suitable photolithography processes. The etching process may be an acceptable anisotropic etching process, such as a reactive ion etch (RIE), neutral beam etch (NBE), the like, or a combination thereof.

The STI regions 56 may be formed by depositing an insulating material in the trenches and over the semiconductor substrate 52, thinning the insulating material to expose the semiconductor substrate 52, and recessing the insulating material in the trenches. The insulating material may comprise silicon oxide, silicon nitride, the like, or a combination thereof, and may be formed by a suitable deposition method, such as chemical vapor deposition (CVD), atomic layer deposition (ALD), the like, or a combination thereof. The thinning process may be a chemical mechanical polishing (CMP), a grinding process, an etch-back process, combinations thereof, or the like. The STI regions 56 may be recessed using an acceptable etching process, such as one that is selective to the material of the insulating material over the material of the semiconductor substrate 52.

Each die region 51 may also comprise an embedded feature 60 encircling the device region 58 in a top-down view. The embedded features 60 are embedded in the semiconductor substrate 52 with a top surface exposed and a bottom surface as well as sidewalls in contact with the semiconductor substrate 52. The embedded features 60 may be formed of a material different from the material of the semiconductor substrate 52, such as a conductive material (e.g., copper, aluminum, etc.) or a dielectric material (e.g., silicon oxide, silicon nitride, etc.). The embedded features 60 may be formed by forming trenches in the semiconductor substrate 52, depositing the material of the embedded features 60 in the trench and on the semiconductor substrate 52, and thinning the material of the embedded features 60 to expose the semiconductor substrate 52. The trenches in which the embedded features 60 are formed may be formed by the same or similar method as the one described above with respect to the STI regions 56. The material of the embedded features 60 may be deposited in the trenches by a suitable deposition method, such as CVD, ALD, physical vapor deposition (PVD), plating, or the like. The thinning process may be the same or similar method as the one described above with respect to the STI regions 56. The embedded features 60 may have a thickness T1. In some embodiments, the thickness T1 is in a range from about 10 nm to about 100 μm.

In some embodiments, the embedded features 60 and the STI regions 56 are formed simultaneously using the same material and the same processes. In such embodiments, the embedded features 60 are also recessed and top surfaces of the embedded features 60 are disposed at a height H1 below the active surface of the semiconductor substrate 52 and level with top surfaces of the STI regions 56. Further, bottom surfaces of the embedded features 60 are disposed at a height H3 and level with bottom surfaces of the STI regions 56.

In some embodiments, the embedded features 60 are formed of a different material and/or by different processes from the STI regions 56. In such embodiments, the top surfaces of the embedded features 60 are substantially coplanar or level with the active surface of the semiconductor substrate 52. Further, the bottom surfaces of the embedded features 60 are disposed at a height H2 (above bottom surfaces of the STI regions 56), a height H3 (level with bottom surfaces of the STI regions 56), or a height H4 (below bottom surfaces of the STI regions 56). The top surfaces of the embedded features 60 may be recessed a same or different amount from the STI regions 56.

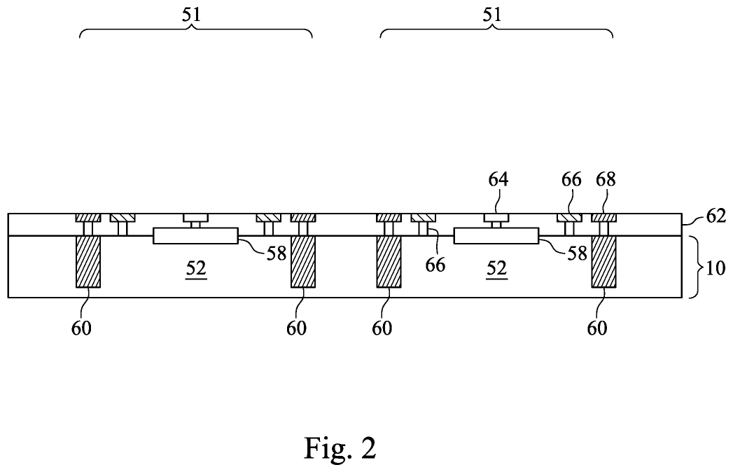

In FIG. 2, an interlayer dielectric (ILD) 62 is formed on the semiconductor substrate 52, and conductive features 64, seal ring segments 66, and protective ring segments 68 are formed in the ILD 62. The conductive features 64, the seal ring segments 66, and the protective ring segments 68 may have line portions and via portions, and may extend through the ILD 62. The conductive features 64, the seal ring segments 66, and the protective ring segments 68 are illustrated as single elements for illustrative purposes. The conductive features 64 may be electrically coupled to the circuitry in the device regions 58. The seal ring segments 66 may extend through the ILD 62 to the semiconductor substrate 52. The protective ring segments 68 may extend through the ILD 62 to contact the embedded features 60. The protective ring segments 68 may comprise the same material as the embedded features 60. The ILD 62 may be formed of a dielectric material and may be deposited by a suitable deposition method, such as CVD, ALD, the like, or a combination thereof. The dielectric material may include an oxide, such as silicon oxide, PSG, BSG, BPSG, a TEOS based oxide, or the like; a nitride, such as silicon nitride or the like; a combination thereof; or the like.

The conductive features 64 and the seal ring segments 66 may be formed simultaneously using the same material and the same processes. The material of the conductive features 64 and the seal ring segments 66 may be conductive material, such as copper, silver, gold, tungsten, cobalt, aluminum, nickel, or the like. The conductive features 64 and the seal ring segments 66 may be formed by a damascene process including forming openings in the ILD 62 using suitable photolithography and etching methods, depositing the conductive material in the openings and on the ILD 62 using a suitable deposition method (e.g., plating, PVD, etc.), and thinning the conductive material to expose the ILD 62 using a suitable thinning method (e.g., CMP, grinding, etc.). In some embodiments, the conductive features 64, the seal ring segments 66, the protective ring segments 68 are formed simultaneously using the same material and the same processes.

In some embodiments, the protective ring segments 68 are formed of a different material and/or by different processes from the conductive features 64 and the seal ring segments 66. In such embodiments, the protective ring segments 68 may comprise a dielectric material different from the dielectric material of the ILD 62 or a conductive material different from the conductive material of the conductive features 64 and the seal ring segments 66. In such embodiments, the protective ring segments 68 may be formed by forming openings in the ILD 62 using suitable photolithography and etching methods, depositing the dielectric material or the conductive material in the openings and on the ILD 62 using a suitable deposition method (e.g., CVD, ALD, PVD, plating, etc.), and thinning the dielectric material or the conductive material to expose the ILD 62 using a suitable thinning method (e.g., CMP, grinding, etc.).

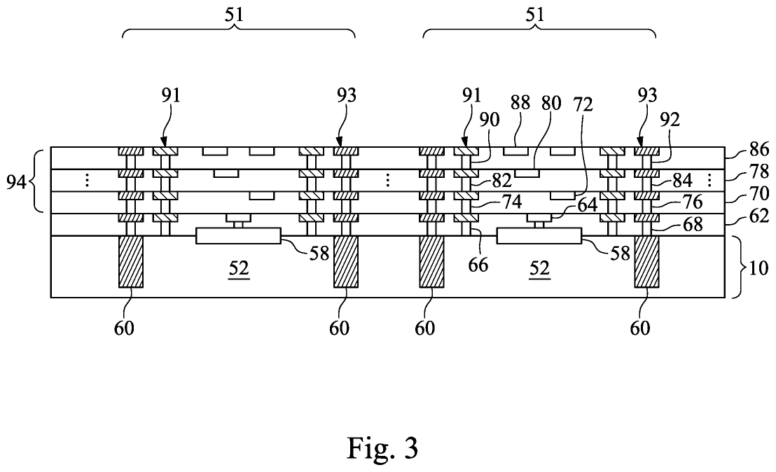

In FIG. 3, an inter-metal dielectric (IMD) 70 is formed on the ILD 62, an IMD 78 is formed on the IMD 70, and an IMD 86 is formed on the IMD 78. Conductive features 72, seal ring segments 74, and protective ring segments 76 are formed in the IMD 70. Conductive features 80, seal ring segments 82, and protective ring segments 84 are formed in the IMD 78. Conductive features 88, seal ring segments 90, and protective ring segments 92 are formed in the IMD 86. The conductive features 64, the conductive features 72, the conductive features 80, and the conductive features 88 may be electrically coupled to form various circuits in the device regions 58. The IMD 70, the IMD 77, the IMD 86, and the conductive features 72, the conductive features 80, and the conductive features 88 may be collectively referred to as the interconnect structure 94. FIG. 3 shows the interconnect structure 94 comprising three layers as an example, in some embodiments, the interconnect structure 94 comprises more or less than three layers.

The seal ring segments 66, the seal ring segments 74, the seal ring segments 82, and the seal ring segments 90 may be connected and form seal rings 91. The embedded features 60, the protective ring segments 68, the protective ring segments 76, the protective ring segments 84, and the protective ring segments 92 may be connected and form the protective rings 93. Each seal ring 91 and each protective ring 93 may provide protection to the features within center regions of the corresponding die region 51 during a subsequent singulation process as discussed in greater detail below. Each embedded feature 60 may be referred to as a bottom portion 60 of the corresponding protective ring 93. The seal rings 91 and the protective rings 93 may be electrically isolated from the circuitry in the device regions 58. FIG. 3 shows the seal rings 91 completely extending through the interconnect structure 94 and the ILD 62 as an example, in some embodiments, the seal rings 91 may partially extend through the interconnect structure 94 and/or the ILD 62. The protective rings 93 may extend through the interconnect structure 94 and the ILD 62, and into the semiconductor substrate 52.

The IMD 70, the IMD 77, and the IMD 86 may be formed of the same or similar material and formed by the same or similar methods as described above with respect to the ILD 62. The conductive features 72, the conductive features 80, and the conductive features 88 may be formed of the same or similar material and formed by the same or similar methods as described above with respect to the conductive features 64. The seal ring segments 74, the seal ring segments 82, and the seal ring segments 90 may be formed of the same or similar material and formed by the same or similar methods as described above with respect to the seal ring segments 66. The protective ring segments 76, the protective ring segments 84, and the protective ring segments 92 may be formed of the same or similar material and formed by the same or similar methods as described above with respect to the protective ring segments 68. Top surfaces of the IMD 86, the conductive features 88, the seal rings 91, and the protective rings 93 may be substantially coplanar or level (within process variations).

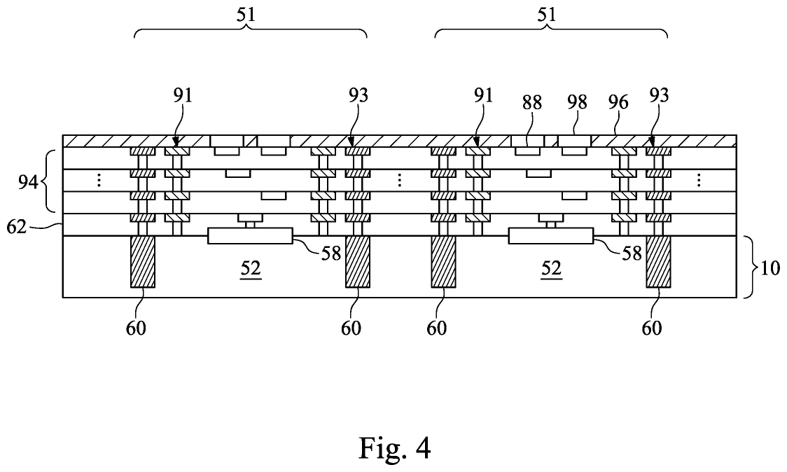

In FIG. 4, a dielectric layer 96 is formed on the interconnect structure 94 and die connectors 98 are formed extending through the dielectric layer 96 to contact the conductive features 88. The dielectric layer 96 may be formed of an oxide, such as silicon oxide, phosphosilicate glass (PSG), borosilicate glass (BSG), boron-doped phosphosilicate glass (BPSG), a tetraethyl orthosilicate (TEOS) based oxide, or the like; a nitride, such as silicon nitride or the like; a combination thereof; or the like. The dielectric layer 96 may be formed by a suitable deposition method, such as CVD, ALD, the like, or a combination thereof. The die connectors 98 may be formed in contact with the conductive features 88 of the interconnect structure 94. As a result, the die connectors 98 may be electrically coupled to the circuitry in the device regions 58. The die connectors 98 may include conductive pillars, pads, or the like, to which external connections can be made. The die connectors 98 may be formed of a conductive material, such as copper, aluminum, or the like, and by a damascene process, such as a single damascene process, a dual damascene process, or the like.

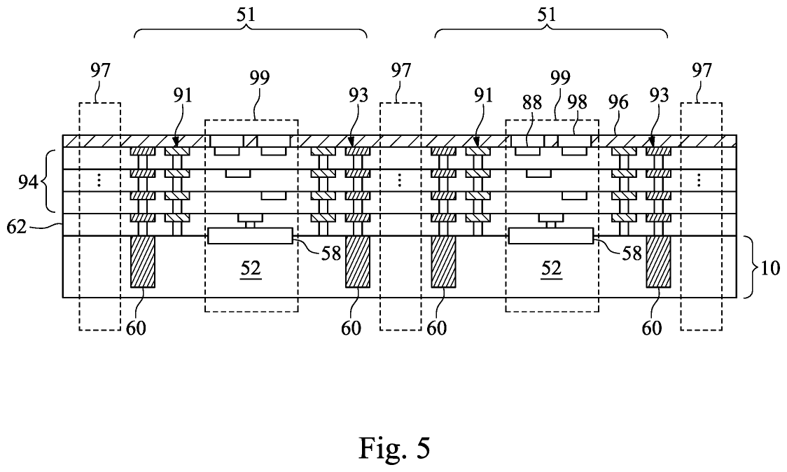

In FIG. 5, the wafer 10 and the overlying structure is singulated into discrete integrated circuit dies 50 (shown in FIGS. 6A and 6B), wherein each die region 51 correspond to one integrated circuit die 50. The singulation process may be done along dicing streets 97 utilizing dicing methods, such as laser dicing, blade dicing, combinations thereof, or the like. Due to the stress induced in the wafer 10 and the overlying structure during the singulation process near the dicing streets 97, cracks may occur in the wafer 10 and the overlying structure near the dicing streets 97. The protective rings 93 may stop the cracks from propagating towards center regions 99 of the die regions 51, where the device regions 58 and conductive features in the ILD 62 and the interconnect structures 94, which form the electrical circuitry of the corresponding integrated circuit dies 50, are disposed. As a result, each protective ring 93 may reduce the risk of cracks in the center region 99 of the corresponding die region 51 and maintain the integrity of the features in the center region 99, such as the semiconductor substrate 52, the device region 58 (including the active devices and/or passive devices within), the ILD 62 (including the conductive features within), and the interconnect structure 94 (including the conductive features within). Each seal ring 91 may provide additional protection to the device region 58 (including the active devices and/or passive devices within), the ILD 62 (including the conductive features within), and the interconnect structure 94 (including the conductive features within) in the center region 99 of the corresponding die region 51 in a similar manner as the protective ring 93. Therefore, the yield and reliability of the resulting integrated circuit dies 50 are improved.

In FIGS. 6A and 6B, the integrated circuit die 50 is shown. The dielectric layer 96 and the die connectors 98 are omitted for illustrative purposes in FIG. 6B. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

An outer edge of the seal ring 91 may be spaced apart from a first edge of the integrated circuit die 50 by a distance D1, wherein the first edge is a closest edge of the integrated circuit die 50 to the outer edge of the seal ring 91. A second edge of the integrated circuit die 50 may be spaced apart from the first edge of the integrated circuit die 50 by a distance D2, wherein the second edge opposes the first edge. The distance D2 may be also referred to as a width of the integrated circuit die 50. When the distance D1 is enlarged relative to the center region 99, the distance D1 may be in a range from about 60 μm to about 120 μm and a ratio R1 of the distance D1 to the distance D2 may be in a range from about 0.004 to about 0.008. As a result, the size of the integrated circuit die 50 may be enlarged relative to a size of the center region 99. An enlarged size of the integrated circuit die 50 may reduce the amount of an encapsulant used to encapsulate the integrated circuit dies 50 during a subsequent manufacturing process, which may reduce the risk of cracks in the encapsulant as described in greater detail below. An enlarged size of the integrated circuit die 50 may be achieved by placing the dicing streets 97 (shown in FIG. 5) further away from the seal rings 91 or narrowing the dicing streets 9 during the singulation process, which may enlarge the size of the integrated circuit die 50 relative to the size of the center region 99 of the integrated circuit die 50.

The protective ring 93 and the seal ring 91 may be rectangular frames, wherein the protective ring 93 may encircle the seal ring 91 and the seal ring 91 may encircle the device region 58 in the top-down view. The protective ring 93 may have a width W1. In some embodiments, the width W1 is in a range from about 10 nm to about 100 μm. The structure and shape of the protective ring 93 shown in FIGS. 6A and 6B are provided as an example. Other structures and shapes of the protective ring 93 are contemplated and examples are discussed in greater detail below.

FIG. 6C shows an integrated circuit die 50A with a structure similar to the integrated circuit die 50 shown in FIG. 6A, wherein like reference numerals refer to like elements, and illustrates embodiments where the bottom portion 60 of the protective ring 93 and the STI region 56 (shown in FIG. 1) in the device region 58 are formed simultaneously using the same material and the same processes. In such embodiments, the bottom portion 60 is recessed and the top surface of the bottom portion 60 is disposed at the height H1 below the active surface of the semiconductor substrate 52 and level with the top surface of the STI region 56 (not shown). Further, the bottom surface of the bottom portion 60 is disposed at a height H3 and level with the bottom surface of the STI region 56. The bottom portion 60 may have a thickness T2, which may be substantially the same as a thickness of the STI region 56. In some embodiments, the thickness T2 is in a range from about 10 nm to about 100 μm. After the bottom portion 60 is recessed, the ILD 62 is formed in the recess and a bottom surface of the ILD 62 is disposed below the active surface of the semiconductor substrate 52.

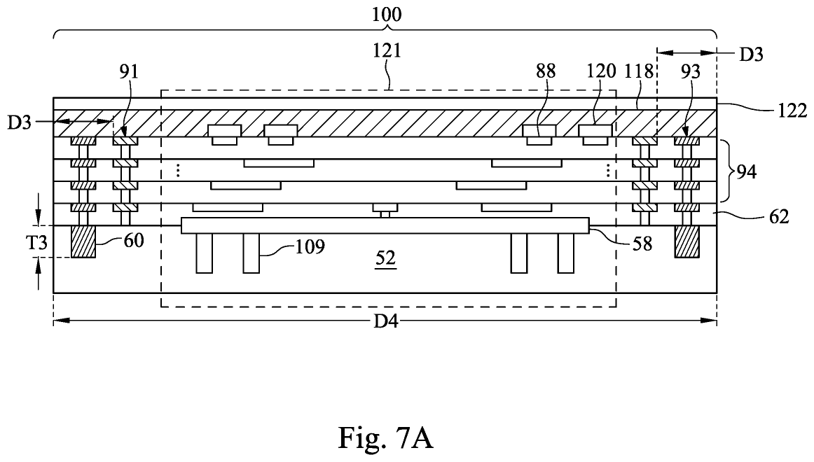

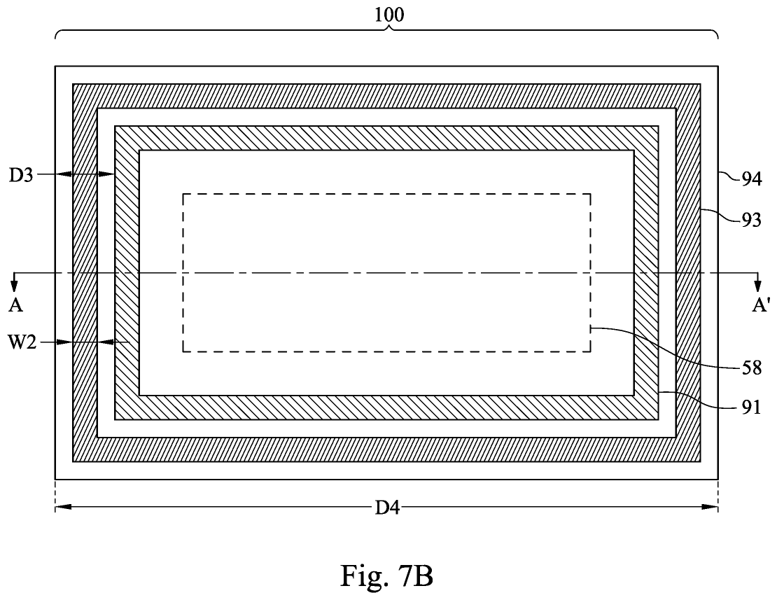

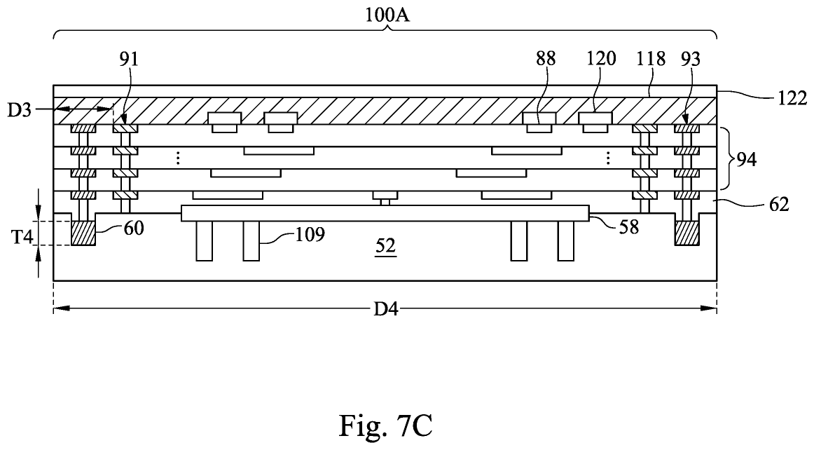

FIGS. 7A and 7B are views of an integrated circuit die 100, in accordance with some embodiments. FIG. 7B is a top-down view and FIG. 7A is a cross-sectional view shown along reference cross-section A-A′ in the top-down view. The integrated circuit die 100 may be similar to the integrated circuit die 50 discussed above, wherein like reference numerals refer to like elements. Certain features are omitted for illustrative purposes in FIG. 7B. The integrated circuit die 100 may be a logic die (e.g., CPU, GPU, SoC, AP, microcontroller, etc.), a memory die (e.g., DRAM die, SRAM die, etc.), a power management die (e.g., PMIC die), a RF die, a sensor die, a MEMS die, a signal processing die (e.g., DSP die), a front-end die (e.g., AFE dies), the like, or combinations thereof. The materials and manufacturing processes of the features in the integrated circuit dies 100 may be found by referring to the like features in the integrated circuit dies 50.

The integrated circuit die 100 may further include conductive vias 109 in the semiconductor substrate 52. The conductive vias 109 may provide a back side electrical contact to the circuitry in the device region 58. The conductive vias 109 may be formed by forming openings in the semiconductor substrate 52 using suitable photolithography and etching methods, and depositing the conductive material in the openings before forming the active devices and/or passive devices in the device region 58. The semiconductor substrate 52 may be thinned in a subsequent manufacturing process to expose the conductive vias 109 at the inactive surface of the semiconductor substrate 52.

A dielectric layer 118 may be on the interconnect structure 94 and die connectors 120 may be embedded in the dielectric layer 118 and in contact the conductive features 88 of the interconnect structure 94. As a result, the die connectors 120 may be electrically coupled to the circuitry in the device region 58. A bonding layer 122 may be disposed on the dielectric layer 118 to attach a carrier wafer in a subsequent process to thin the semiconductor substrate to expose the conductive vias 109. The bonding layer 122 may comprise a dielectric material, such as silicon dioxide, silicon nitride, or the like, and may be formed by a suitable deposition process such as CVD, ALD, or the like.

The integrated circuit die 100 may further comprise a seal ring 91 and a protective ring 93. Similar to the top integrated circuit dies 50, the integrated circuit die 100 may also be formed as a part of a wafer and subsequently singulated to form discrete integrated circuit dies 100. The singulation process may be the same or similar to the singulation process that forms the integrated circuit dies 50. The protective ring 93 and the seal ring 91 may provide the same or similar protection to the features in a center region 121 of the integrated circuit die 100 during the singulation process, as described with respect to the integrated circuit dies 50, thereby improving the yield and reliability of the resulting integrated circuit dies 100.

In the integrated circuit die 100, the bottom portion 60 of the protective ring 93 may have a thickness T3. In some embodiments, the thickness T3 is in a range from about 10 nm to about 100 μm. The protective ring 93 may have a width W2 (see FIG. 7B). In some embodiments, the width W2 is in a range from about 10 nm to about 100 μm. An outer edge of the seal ring 91 may be spaced apart from a first edge of the integrated circuit die 100 by a distance D3, wherein the first edge is a closest edge of the integrated circuit die 100 to the outer edge of the seal ring 91. A second edge of the integrated circuit die 100 may be spaced apart from the first edge of the integrated circuit die 100 by a distance D4, wherein the second edge opposes the first edge. The distance D4 may be also referred to as a width of the integrated circuit die 100. When the distance D3 is enlarged relative to a width of the center region 121, the distance D3 may be in a range from about 60 μm to about 120 μm and a ratio R2 of the distance D3 to the distance D4 may be in a range from about 0.004 to about 0.008. As a result, the size of the integrated circuit die 100 may be enlarged relative to a size of the center region 121. An enlarged size of the integrated circuit die 100 may reduce the amount of an encapsulant used to encapsulate integrated circuit die 100 during a subsequent manufacturing process, which may reduce the risk of cracks in the encapsulant as described in greater detail below. An enlarged size of the integrated circuit die 100 may be achieved by the same or similar methods during the singulation process as described above with respect to the integrated circuit die 50.

FIG. 7C shows an embodiment of the integrated circuit die 100A with a structure similar to the integrated circuit die 100 shown in FIG. 7A, wherein like reference numerals refer to like elements, and illustrates embodiments wherein the bottom portion 60 of the protective ring 93 and a STI region (not shown) in the device region 58 are formed simultaneously using the same material and the same processes. In such embodiments, the bottom portion 60 is recessed and a top surface of the bottom portion 60 is disposed below the active surface of the semiconductor substrate 52 and level with a top surface of the STI region. Further, a bottom surface of the bottom portion 60 is level with a bottom surface of the STI region. The bottom portion 60 may have a thickness T4, which may be substantially the same as a thickness of the STI region. In some embodiments, the thickness T4 is in a range from about 10 nm to about 100 μm. After the bottom portion 60 is recessed, the ILD 62 is formed in the recess and a bottom surface of the ILD 62 is disposed below the active surface of the semiconductor substrate 52.

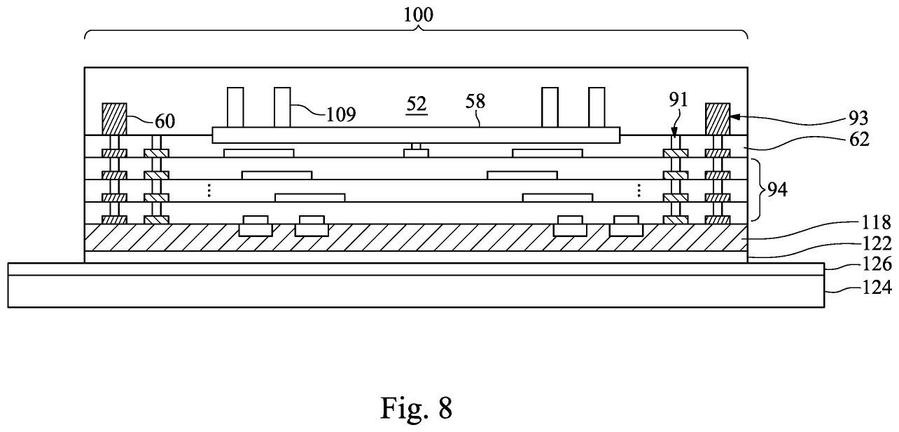

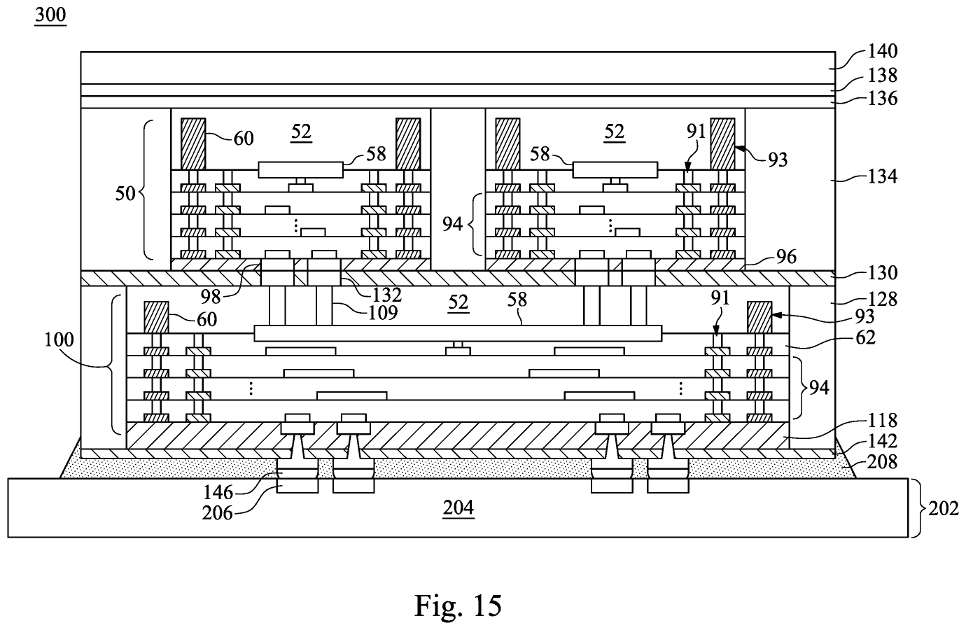

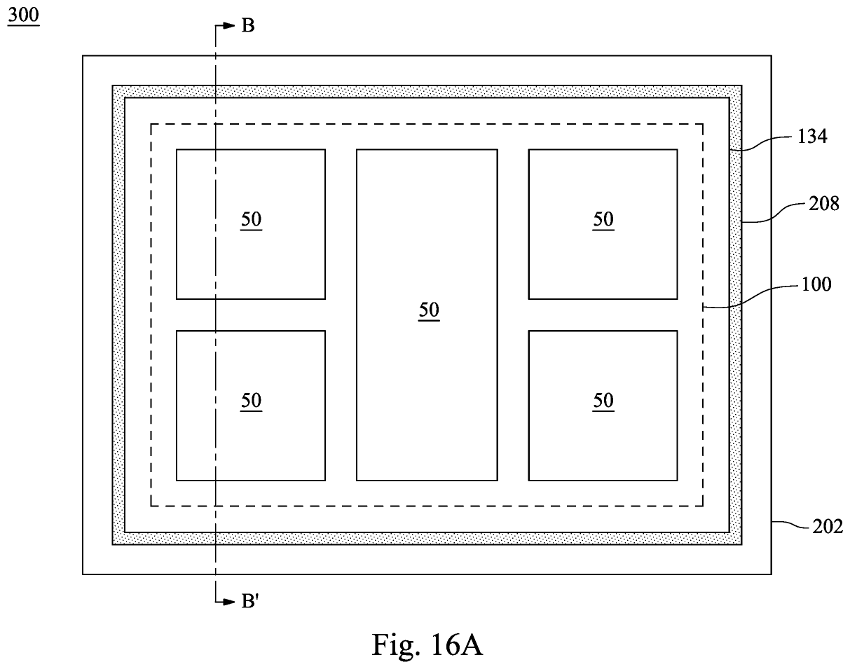

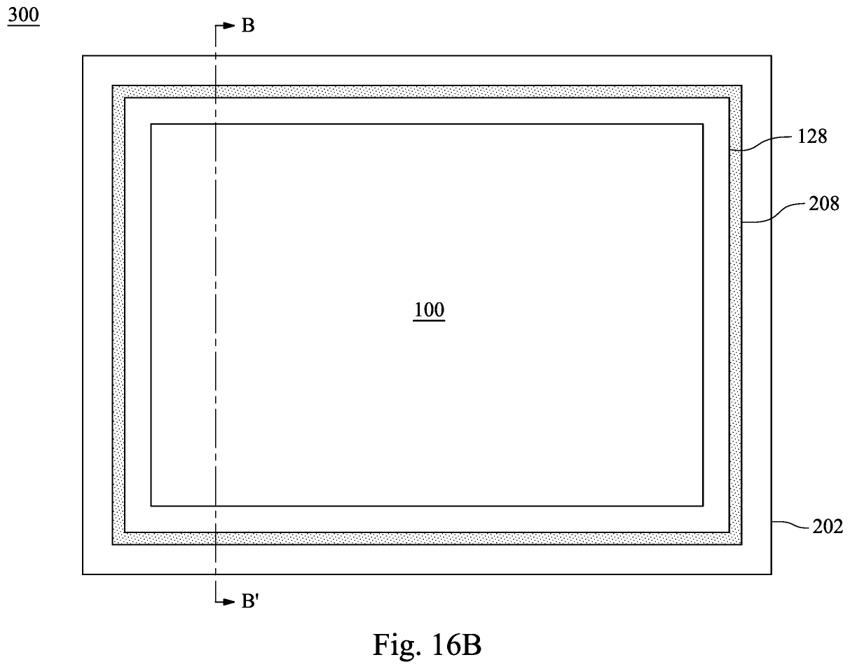

FIGS. 8 through 16B are views of intermediate stages in the manufacturing of an integrated circuit package 300, in accordance with some embodiments. As discussed in greater detail below, the integrated circuit die 100 and the integrated circuit dies 50 are packaged together to form the integrated circuit package 300. The integrated circuit die 100 is positioned on a bottom tier and is also referred to as a bottom integrated circuit die 100. The integrated circuit dies 50 are positioned over the bottom integrated circuit die 100 on a top tier and is also referred to as a top integrated circuit dies 50. FIGS. 16A and 16B are top-down views. FIGS. 8, 9, 10, 11, 12, 13, 14, and 15 are cross-sectional views shown along reference cross-section B-B′ in the top-down views. An example layout of the top integrated circuit dies 50 and the bottom integrated circuit die 100 is shown in FIGS. 15, 16A, and 16B, other layouts with more or less top integrated circuit dies 50 and bottom integrated circuit dies 100 of various arrangements are contemplated.

Referring first to FIG. 8, the bottom integrated circuit die 100 is bonded to a carrier 124. The carrier 124 may be a semiconductor carrier, a glass carrier, a ceramic carrier, or the like. The carrier 124 may be a wafer. FIG. 8 illustrates one bottom integrated circuit die 100 bonded to the carrier 124 as an example, two or more bottom integrated circuit dies 100 may be bonded to the carrier 124 and processed together during the subsequent manufacturing steps until singulated into individual package components. One or more bonding layers may be disposed on the carrier 124. In some embodiments, a bonding layer 126 is disposed on the carrier 124. The bonding layer 126 may comprise a dielectric material, such as silicon dioxide, silicon nitride, or the like, and may be formed by a suitable deposition method, such as CVD, ALD, or the like.

The bottom integrated circuit die 100 may be bonded to the bonding layer 126 by placing the bottom integrated circuit die 100 on the bonding layer 126 by a pick-and-place process or the like, then bonding the bottom integrated circuit die 100 to the bonding layer 126. As an example of the bonding process, the bottom integrated circuit die 100 may be bonded to the bonding layer 126 by dielectric-to-dielectric bonding without using an adhesive material (e.g., die attach film). The bonding may include a pre-bonding and an annealing. During the pre-bonding, a small pressing force is applied to press the bottom integrated circuit die 100 against the bonding layer 126. The pre-bonding is performed at a low temperature, such as room temperature, and after the pre-bonding, the bonding layer 122 is bonded to the bonding layer 126. The bonding strength is then improved in a subsequent annealing step, in which the bonding layer 122 and the bonding layer 126 are annealed. After the annealing, direct bonds such as covalent bonds are formed between the bonding layer 122 of the bottom integrated circuit die 100 and the bonding layer 126 of the carrier 124.

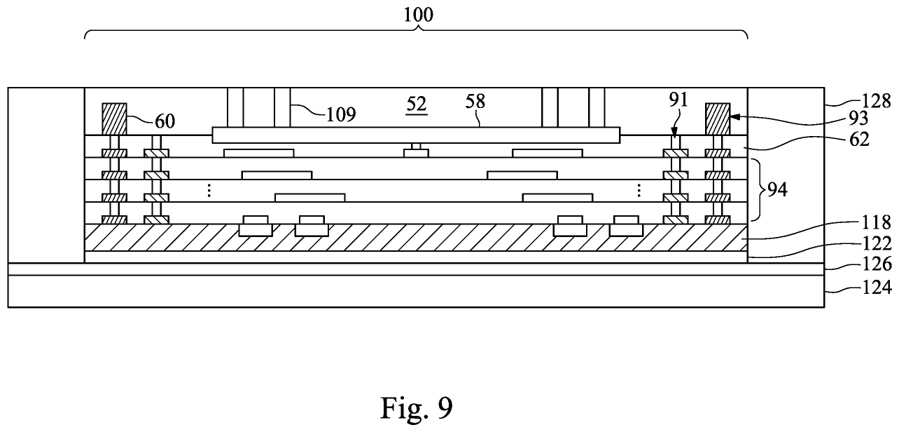

In FIG. 9, a bottom encapsulant 128 is formed around the bottom integrated circuit die 100 and between the neighboring bottom integrated circuit dies 100 (not shown) over the carrier 124. The bottom encapsulant 128 may have a coefficient of thermal expansion (CTE) larger than a CTE of the bottom integrated circuit die 100, which may result in a CTE mismatch between the bottom encapsulant 128 and the bottom integrated circuit die 100. The CTE mismatch may cause cracks in the bottom encapsulant 128 during subsequent manufacturing processes, which may be mitigated by reducing the amount of the bottom encapsulant 128 used during the encapsulation process as discussed in greater detail below.

In some embodiments, the bottom encapsulant 128 is formed of organic dielectric material(s), such as polymer molding compound (e.g., epoxy and resin) or the like, which is formed by a suitable deposition process, such as compression molding, transfer molding, or the like followed by a curing process. In some embodiments, the bottom encapsulant 128 is formed of inorganic dielectric material(s), such as silicon oxide, silicon nitride, or the like, which is formed by a suitable deposition process, such as CVD, ALD, or the like. Initially, the bottom encapsulant 128 may bury or cover the back side of the semiconductor substrate 52. A thinning process may be performed to remove the bottom encapsulant 128 from over the bottom integrated circuit die 100 and to expose the conductive vias 109. The thinning process may be a CMP, a grinding process, an etch-back process, combinations thereof, or the like. After the thinning process, surfaces of the bottom encapsulant 128 and the bottom integrated circuit die 100 (including the semiconductor substrate 52 and the conductive vias 109) may be substantially coplanar or level (within process variations).

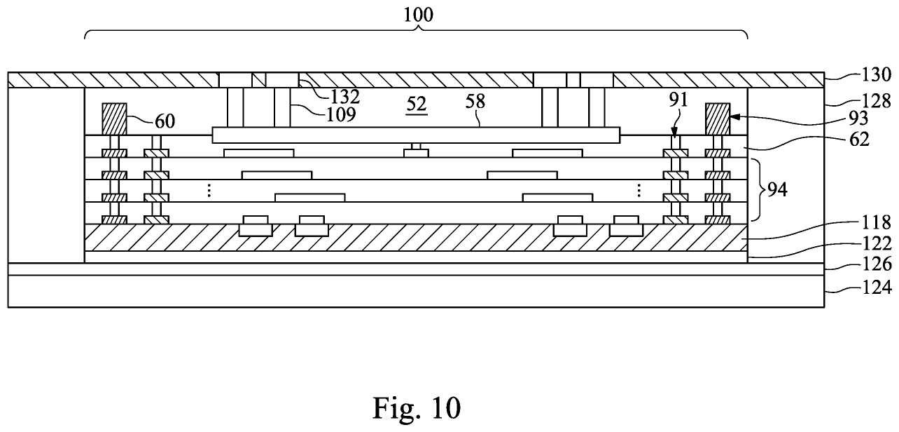

In FIG. 10, a dielectric layer 130 is formed on the bottom encapsulant 128 and the back side of the semiconductor substrate 52, and die connectors 132 are formed in the dielectric layer 130. The die connectors 132 may extend through the dielectric layer 130 and connect to the conductive vias 109. The dielectric layer 130 may electrically isolate the die connectors 132 from one another, thus avoiding shorting, and may also be utilized in a subsequent bonding process. The dielectric layer 130 may be formed of an oxide such as silicon oxide, PSG, BSG, BPSG, a TEOS based oxide, or the like, which may be formed by a suitable deposition process such as CVD, ALD, or the like. The die connectors 132 may be formed by a damascene process, such as a single damascene process, a dual damascene process, or the like. The die connectors 132 may be formed of a metal, such as copper, aluminum, or the like, which can be formed by plating, or the like. In some embodiments, a planarization process such as a CMP, a grinding process, an etch-back process, combinations thereof, or the like, is performed on the dielectric layer 130 and the die connectors 132. After the planarization process, surfaces of the dielectric layer 130 and the die connectors 132 may be substantially coplanar or level (within process variations).

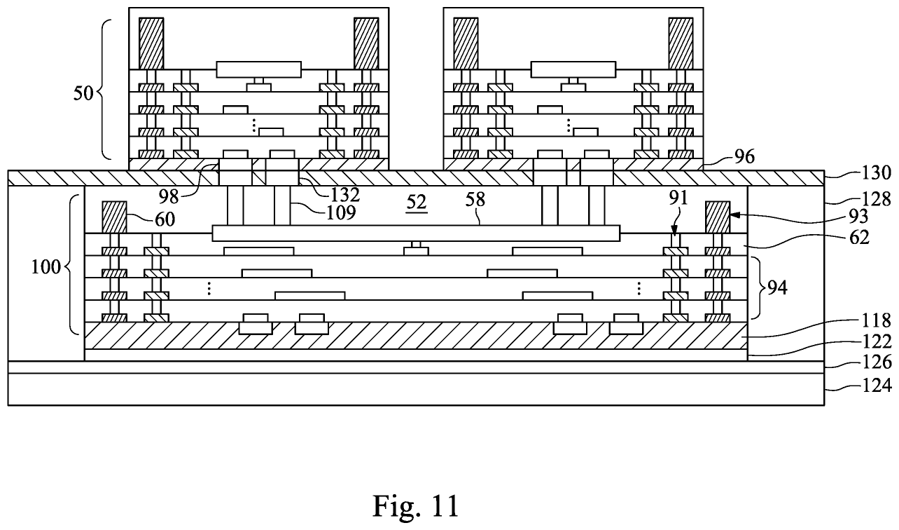

In FIG. 11, the top integrated circuit dies 50 are bonded to the dielectric layer 130 and the die connectors 132. The die connectors 132 electrically couple the top integrated circuit dies 50 to the bottom integrated circuit die 100. The top integrated circuit dies 50 may be bonded to the dielectric layer 130 and the die connectors 132 by placing the top integrated circuit dies 50 on the dielectric layer 130 and the die connectors 132 by a pick-and-place process or the like, then bonding the top integrated circuit dies 50 to the dielectric layer 130 and the die connectors 132.

The top integrated circuit dies 50 may be bonded to the dielectric layer 130 and the die connectors 132 by dielectric-to-dielectric bonding and metal-to-metal bonding. The dielectric layers 96 of the top integrated circuit dies 50 are directly bonded to the dielectric layer 130 through dielectric-to-dielectric bonding, without using an adhesive material (e.g., die attach film). The die connectors 98 of the top integrated circuit die 50 are directly bonded to respective die connectors 132 through metal-to-metal bonding, without using a eutectic material (e.g., solder). The bonding may include a pre-bonding and an annealing. During the pre-bonding, a small pressing force is applied to press the top integrated circuit dies 50 against the dielectric layer 130 and the die connectors 132. The pre-bonding is performed at a low temperature, such as room temperature, and after the pre-bonding, the dielectric layer 96 is bonded to the dielectric layer 130. The bonding strength may be improved in a subsequent annealing step. After the annealing, direct bonds such as covalent bonds are formed between the dielectric layer 130 and the dielectric layer 96. The die connectors 132 are connected to corresponding ones of the die connectors 98. The die connectors 132 and the die connectors 98 may be in physical contact after the pre-bonding, or may expand to be brought into physical contact during the annealing. Further, during the annealing, the material of the die connectors 132 and the die connectors 98 intermingle, so that metal-to-metal bonds are also formed.

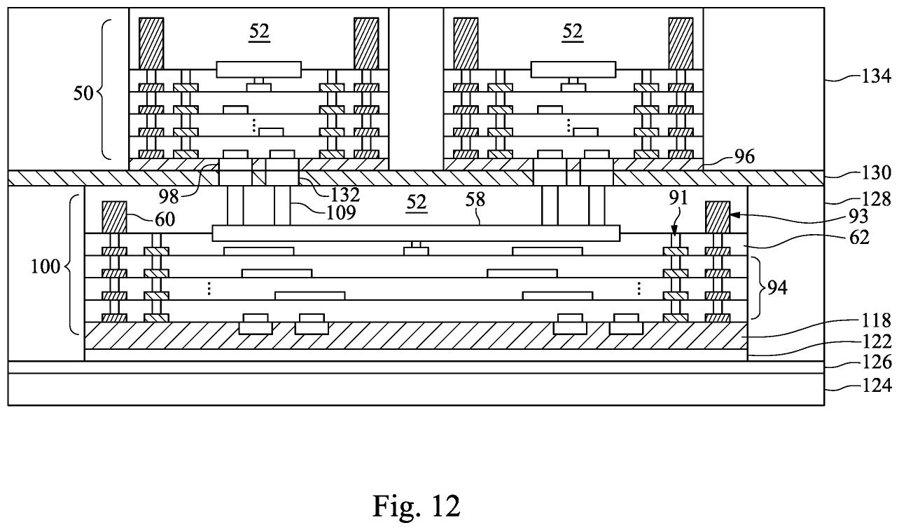

In FIG. 12, a top encapsulant 134 is formed around the top integrated circuit die 50 and between the neighboring top integrated circuit dies 50 over the dielectric layer 130. The top encapsulant 134 may have a CTE larger than a CTE of the top integrated circuit dies 50, which may result in a CTE mismatch between the top encapsulant 134 and the top integrated circuit dies 50. The CTE mismatch may cause cracks in the top encapsulant 134 during subsequent manufacturing processes, which may be mitigated by reducing the amount of the top encapsulant 134 during the encapsulation process used as discussed in greater detail below.

In some embodiments, the top encapsulant 134 is formed of organic dielectric material(s), such as polymer molding compound (e.g., epoxy and resin) or the like, which is formed by a suitable deposition process, such as compression molding, transfer molding, or the like followed by a curing process. In some embodiments, the top encapsulant 134 is formed of inorganic dielectric material(s), such as silicon oxide, silicon nitride, or the like, which is formed by a suitable deposition process, such as CVD, ALD, or the like. The top encapsulant 134 may be formed of the same or similar dielectric material and by a same or similar method as the bottom encapsulant 128. Initially, the top encapsulant 134 may bury or cover the back side of the top integrated circuit dies 50. A thinning process may be performed to remove portions of the semiconductor substrate 52 and the top encapsulant 134. The thinning process may be a CMP, a grinding process, an etch-back process, combinations thereof, or the like. After the thinning process, surfaces of the top encapsulant 134, the top integrated circuit die 50 (including the semiconductor substrate 52) may be substantially coplanar or level (within process variations).

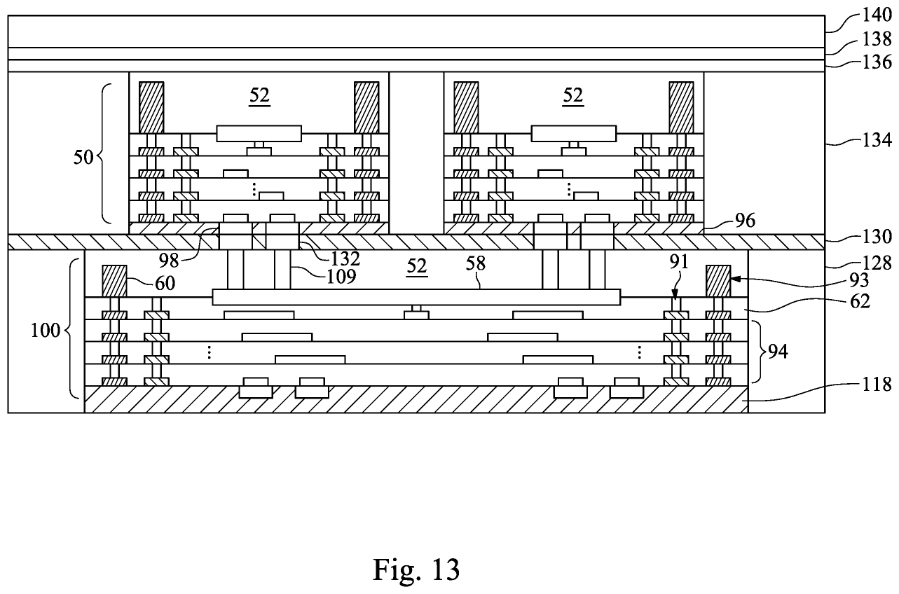

In FIG. 13, a bonding layer 136 is formed on the semiconductor substrate 52 and the top encapsulant 134, and the bonding layer 136 is bonded to a carrier 140. Then the carrier 124, the bonding layer 126, and the bonding layer 122 (shown in FIG. 12) are removed. The bonding layer 136 may comprise a dielectric material, such as silicon dioxide, silicon nitride, or the like, and may be formed by a suitable deposition process such as CVD, ALD, or the like. The carrier 140 may be a semiconductor carrier, a glass carrier, a ceramic carrier, or the like. The carrier 140 may be a wafer having a same or similar size as the carrier 124. One or more bonding layers may be disposed on the carrier 140. In some embodiments, a bonding layer 138 is disposed on the carrier 140. The bonding layer 138 may comprise a dielectric material, such as silicon dioxide, silicon nitride, or the like, and may be formed by a suitable deposition method, such as CVD, ALD, or the like. The carrier 124, the bonding layer 126, and the bonding layer 122 is then removed by a thinning process. A portion of the bottom encapsulant 128 may be also removed and the dielectric layer 118 may be exposed. The thinning process may be a CMP, a grinding process, an etch-back process, combinations thereof, or the like. After the thinning process, the dielectric layer 118 and the bottom encapsulant 128 may be substantially coplanar or level (within process variations).

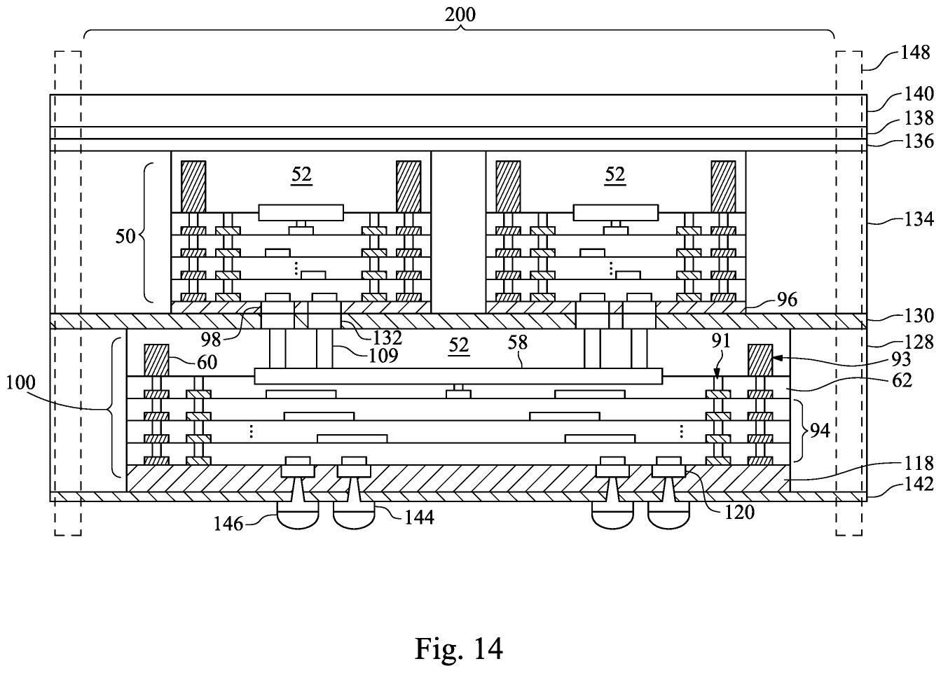

In FIG. 14, a dielectric layer 142 is formed on the dielectric layer 118 and the bottom encapsulant 128, under-bump metallizations (UBMs) 144 are formed on and through the dielectric layer 142, and electrical connectors 146 are formed on the UBMs 144. Then the structure shown in FIG. 14 is singulated along dicing streets 148 utilizing dicing methods, such as laser dicing, blade dicing, combinations thereof, or the like, so that the structure shown in FIG. 14 is separated into discrete integrated circuit package components 200. The dielectric layer 142 may comprise silicon dioxide, silicon nitride, or the like, and may be formed by a suitable deposition process such as CVD, ALD, or the like. The dielectric layer 142 may be a passivation layer. The UBMs 144 have bump portions on and extending along a surface of the dielectric layer 142, and have via portions extending through the dielectric layer 142 and the dielectric layer 118 to physically and electrically couple to the die connectors 120. As a result, the UBMs 144 are electrically coupled to the bottom integrated circuit die 100. The singulation process may include a sawing process, a laser cutting process, or the like. A cleaning process or rinsing process may be performed after the singulation process.

As an example to form the UBMs 144, the dielectric layer 142 and the dielectric layer 118 are patterned to form openings exposing the underlying die connectors 120. The patterning may be done by an acceptable photolithography and etching processes, such as by forming a mask then performing an anisotropic etching. The mask is removed after the patterning. A seed layer (not shown) is formed on the dielectric layer 142, in the openings through the dielectric layer 142 and the dielectric layer 118, and on the exposed portions of the die connectors 120. A photoresist is then formed and patterned on the seed layer. The pattern of the photoresist corresponds to the UBMs 144. The patterning forms openings through the photoresist to expose the seed layer. A conductive material is formed in the openings of the photoresist and on the exposed portions of the seed layer by plating, such as electroless plating or electroplating, or the like. The conductive material may comprise a metal or a metal alloy, such as copper, titanium, tungsten, aluminum, the like, or combinations thereof. Then, the photoresist and portions of the seed layer on which the conductive material is not formed are removed. The remaining portions of the seed layer and conductive material form the UBMs 144.

Electrical connectors 146 are formed on the UBMs 144. The electrical connectors 146 may be ball grid array (BGA) connectors, solder balls, metal pillars, controlled collapse chip connection (C4 ) bumps, micro bumps, electroless nickel-electroless palladium-immersion gold technique (ENEPIG) formed bumps, or the like. The electrical connectors 146 may include a conductive material such as solder, copper, aluminum, gold, nickel, silver, palladium, tin, the like, or a combination thereof. In some embodiments, the electrical connectors 146 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the electrical connectors 146 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars.

In FIG. 15, the integrated circuit package component 200 is bonded to a package substrate 202 and an underfill 208 is formed between the integrated circuit package component 200 and the package substrate 202. The resulting structure may be referred to as the integrated circuit package 300. The package substrate 202 includes a substrate 204 and bond pads 206 over the substrate 204. In some embodiments, the substrate 204 are formed of a semiconductor material, such as silicon, germanium, or the like, or compound materials, such as silicon germanium, silicon carbide, gallium arsenic, indium arsenide, indium phosphide, silicon germanium carbide, gallium arsenic phosphide, gallium indium phosphide, combinations thereof, or the like. In some embodiments, the substrate 204 is formed of an insulating material, such as fiberglass reinforced resin, bismaleimide triazine (BT) resin, Ajinomoto build-up film (ABF), or the like.

The substrate 204 may include active and/or passive devices (not shown), such as transistors, capacitors, resistors, combinations thereof, or the like. The active and/or passive devices may be formed using any suitable methods. The substrate 204 may also include metallization layers and vias, with the bond pads 206 being physically and electrically coupled to the metallization layers and vias. The metallization layers may be formed over the active and/or passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process, such as damascene, dual damascene, or the like.

During the bonding process the electrical connectors 146 may be reflowed to bond the integrated circuit package component 200 to the bond pads 206. The electrical connectors 146 electrically and physically couple the package substrate 202 to the integrated circuit package component 200. In some embodiments, a solder resist (not shown) is formed on the substrate 204. The electrical connectors 146 may be disposed in openings in the solder resist to be electrically and physically coupled to the bond pads 206. The solder resist may be used to protect areas of the substrate 204 from external damage.

An underfill 208 is formed between the integrated circuit package component 200 and the package substrate 202, surrounding the electrical connectors 146. The underfill 208 may reduce stress and protect the joints resulting from the reflowing of the electrical connectors 146. The underfill 208 may be formed by a capillary flow process after the integrated circuit package component 200 is bonded, or may be formed by a suitable deposition method before the integrated circuit package component 200 is attached. The underfill 208 may be subsequently cured.

FIG. 16A shows a top-down view of the integrated circuit package 300 shown in FIG. 15, wherein the features over the top integrated circuit dies 50 and the top encapsulant 134 are omitted for illustrative purposes. The layout of the top integrated circuit dies 50 on the bottom integrated circuit die 100 shown in FIG. 16A is an example, other layouts with more or less top integrated circuit dies 50 of various arrangements are contemplated. As discussed above, there may be a CTE mismatch between the top integrated circuit dies 50 and the top encapsulant 134 that encircles the top integrated circuit dies 50, which may cause cracks in the top encapsulant 134 during subsequent manufacturing processes or the usage of the integrated circuit package 300. The risk of cracks may be reduced by reducing the amount of the top encapsulant 134 used during the encapsulation process, which may be achieved by enlarging the sizes of the top integrated circuit dies 50. Therefore, enlarged distances D1 in top integrated circuit dies 50 (shown in FIGS. 6A and 6B), which may lead to enlarged sizes of the top integrated circuit dies 50, may result in a decreased risk of cracks in the top encapsulant 134, therefore an improved reliability of the integrated circuit package 300. A total area of the top integrated circuit dies 50 in the top-down view is area A1 and a total area of the top encapsulant 134 in the top-down view is area A2. In some embodiments, a ratio R3 of the area A1 to the area A2 is in a range from about 2 to about 3.

FIG. 16B shows a top-down view of the integrated circuit package 300 shown in FIG. 15, wherein the features over the bottom integrated circuit die 100 and the bottom encapsulant 128 are omitted for illustrative purposes. The layout of the bottom integrated circuit die 100 shown in FIG. 16A is an example, other layouts with more bottom integrated circuit dies 100 of various arrangements are contemplated. For similar reasons described above with respect to FIG. 16A, enlarged distances D3 (shown in FIGS. 7A and 7B) in the bottom integrated circuit die 100, which may lead to an enlarged size of the bottom integrated circuit die 100, may result in a decreased risk of cracks in the bottom encapsulant 128, therefore an improved reliability of the integrated circuit package 300. A total area of the bottom integrated circuit die 100 in the top-down view is area A3 and a total area of the bottom encapsulant 128 in the top-down view is area A4. In some embodiments, a ratio R4 of the area A3 to the area A4 is in a range from about 2 to about 3.

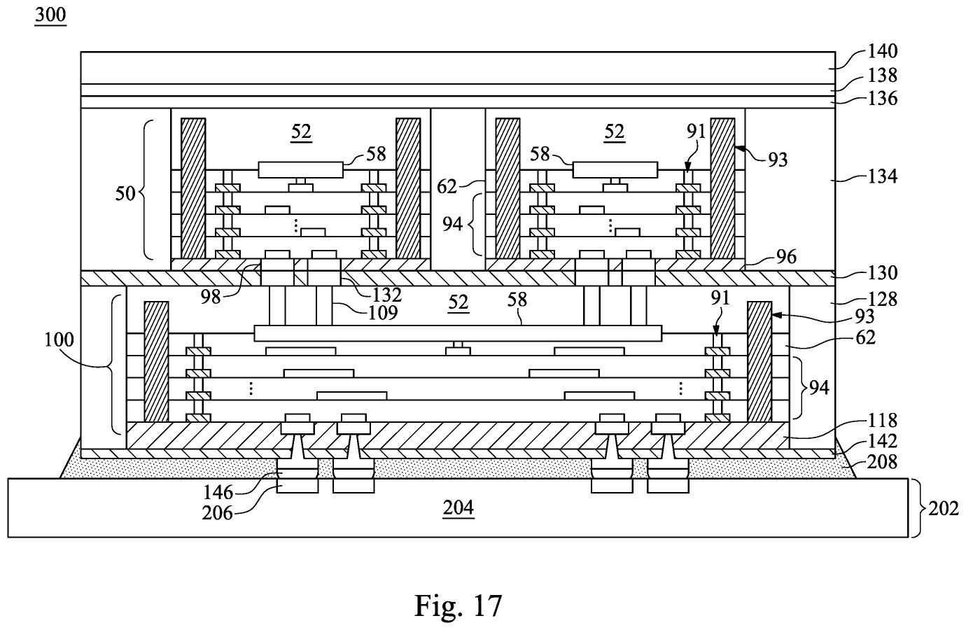

FIG. 17 shows a cross-sectional view of an integrated circuit package 300 with a structure similar to the structure shown in FIG. 15, wherein like reference numerals refer to like elements, and illustrates the embodiments where the protective rings 93 in the top integrated circuit dies 50 are formed after the interconnect structure 94 is formed, and the protective ring 93 in the bottom integrated circuit die 100 is formed after the interconnect structure 94 is formed. The protective ring 93 may be formed by forming an opening through the interconnect structure 94, the ILD 62, and into the semiconductor substrate 52 using one or more suitable photolithography and etching methods, depositing the dielectric material or the conductive material in the opening and on the interconnect structure 94 using a suitable deposition method (e.g., CVD, ALD, PVD, plating, etc.), and thinning the dielectric material or the conductive material to expose the interconnect structure 94 using a suitable thinning method (e.g., CMP, grinding, etc.). As a result, the protective rings 93 and the protective ring 93 may have continuous sidewalls extending from top surfaces to bottom surfaces.

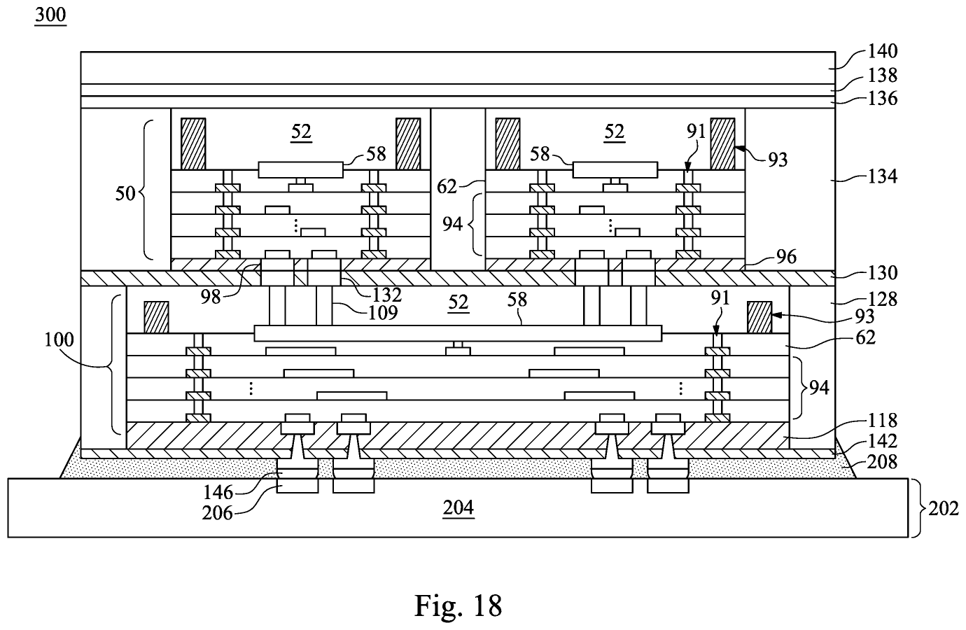

FIG. 18 shows a cross-sectional view of an integrated circuit package 300 with a structure similar to the structure shown in FIG. 15, wherein like reference numerals refer to like elements, and illustrates embodiments where the protective rings 93 in the top integrated circuit dies 50 are formed only in the semiconductor substrate 52, and the protective ring 93 in the bottom integrated circuit die 100 is formed only in the semiconductor substrate 52. The bottom surfaces of the protective rings 93 (the surfaces in contact with the ILD 62) and the active surfaces of the semiconductor substrates 52 may be substantially coplanar or level (within process variations).

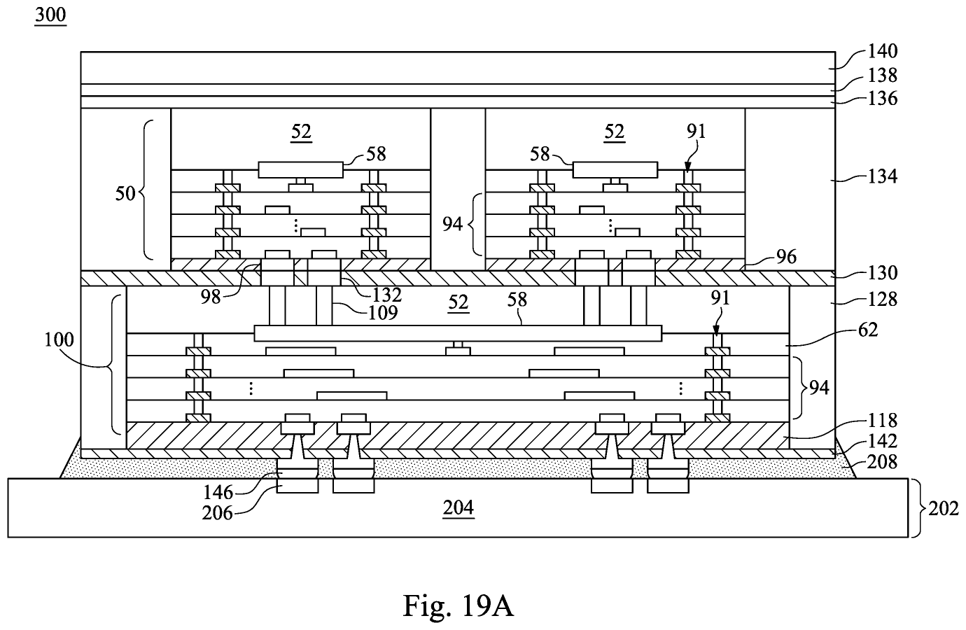

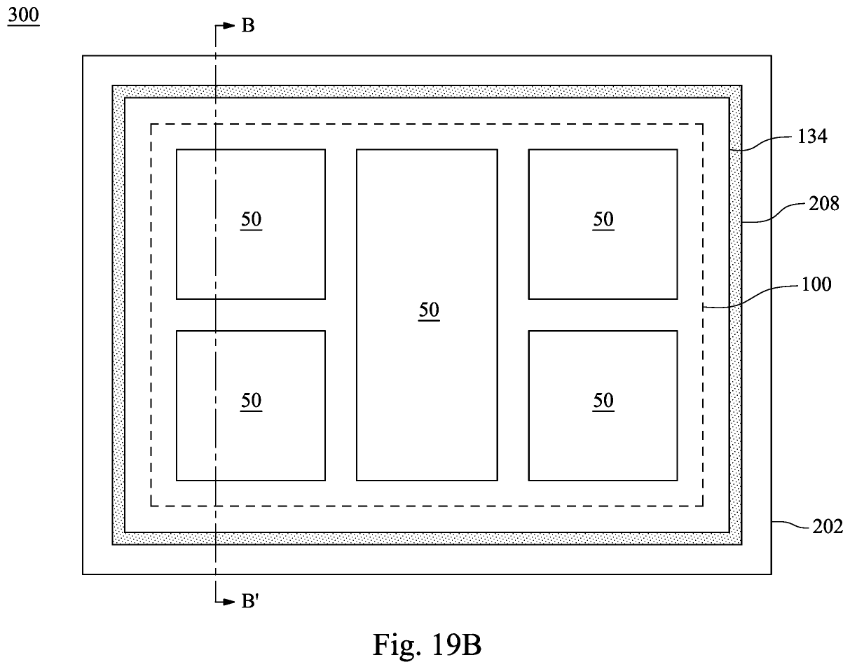

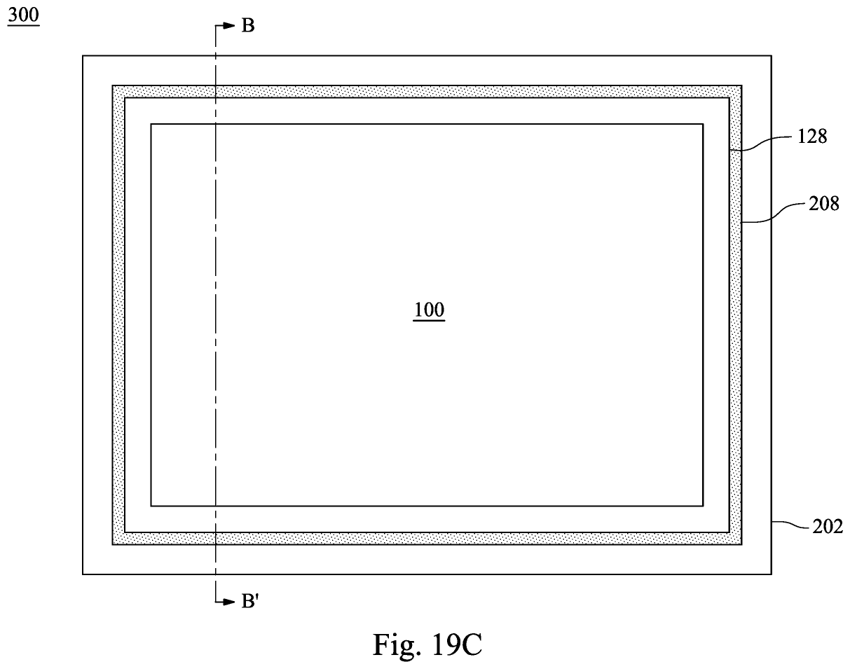

FIG. 19A shows a cross-sectional view of an integrated circuit package 300 with a structure similar to the structure shown in FIG. 15, wherein like reference numerals refer to like elements, and illustrates embodiments where the protective rings 93 are not formed in the top integrated circuit dies 50 or in the bottom integrated circuit die 100. FIG. 19B shows a top-down view of the integrated circuit package 300 shown in FIG. 19A, wherein the features over the top integrated circuit dies 50 and the top encapsulant 134 are omitted for illustrative purposes. As described above with respect to FIGS. 16A and 16B, the risk of cracks in the top encapsulant 134 may be reduced by reducing the amount of the top encapsulant 134 used during the encapsulation process, which may be achieved by enlarging the sizes of the top integrated circuit dies 50, and the risk of cracks in the bottom encapsulant 128 may be reduced by reducing the amount of the bottom encapsulant 128 used during the encapsulation process, which may be achieved by enlarging the sizes of the top integrated circuit dies 50. A total area of the top integrated circuit dies 50 in the top-down view is area A5 and a total area of the top encapsulant 134 in the top-down view is area A6. In some embodiments, a ratio R5 of the area A5 to the area A6 is in a range from about 2 to about 3. FIG. 19C shows a top-down view of the integrated circuit package 300 shown in FIG. 19A, wherein the features over the bottom integrated circuit die 100 and the bottom encapsulant 128 are omitted for illustrative purposes. A total area of the bottom integrated circuit die 100 in the top-down view is area A7 and a total area of the bottom encapsulant 128 in the top-down view is area A8. In some embodiments, a ratio R6 of the area A7 to the area A8 is in a range from about 2 to about 3.

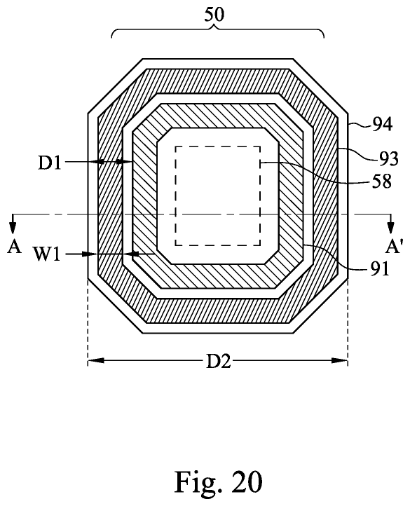

FIG. 20 shows a top-down view of an integrated circuit die 50 with a structure similar to the structure shown in FIG. 6B, wherein like reference numerals refer to like elements, and illustrates embodiments wherein the top integrated circuit die 50 has a shape of a rectangle with chamfered corners (e.g., octagon). Accordingly, the seal ring 91 and the protective ring 93 may be rectangular frames with chamfered corners (e.g., octagonal frames). The integrated circuit die 100, and seal ring 91 as well as the protective ring 93 in the integrated circuit die 100, may also have same or similar structures and/or shapes.

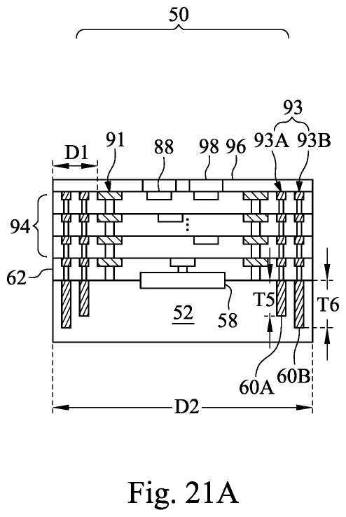

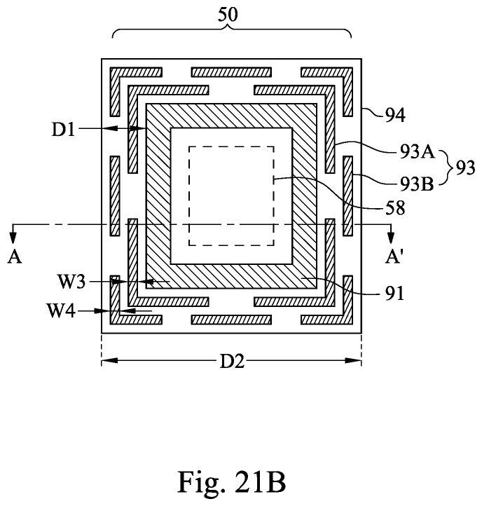

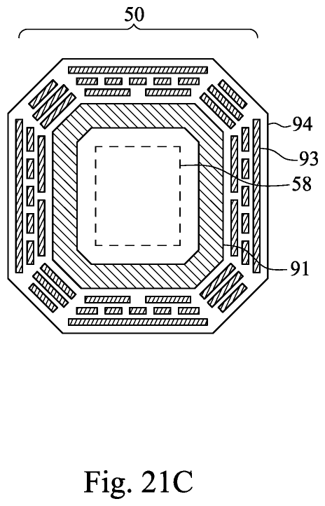

FIGS. 21A and 21B illustrate views of an integrated circuit die 50 with a structure similar to the structures shown in FIGS. 6A and 6B, respectively, wherein like reference numerals refer to like elements, and illustrate embodiments wherein two protective rings 93 (protective ring 93A and protective ring 93B) are disposed in the top integrated circuit die 50. FIG. 21B is a top-down view and FIG. 21A is a cross-sectional view shown along reference cross-section A-A′ in the top-down view.

The protective ring 93A and the protective ring 93B may be concentric fragmented rings encircling the seal ring 91. In some embodiments, the top integrated circuit die 50 has a shape of a rectangle as shown in FIG. 21B. Accordingly, the seal ring 91, the protective ring 93A, and the protective ring 93B may be rectangular frames. In some embodiments (not shown), the top integrated circuit die 50 has a shape of a rectangle with chamfered corners (e.g., octagon). Accordingly, the seal ring 91, the protective ring 93A, and the protective ring 93B may be rectangular frames with chamfered corners (e.g., octagonal frames). The protective ring 93A may have a width W3 and protective ring 93B may have a width W4. The width W3 and the width W4 may be the same or different. A bottom portion 60A of the protective ring 93A may have a thickness T5 and a bottom portion 60B of the protective ring 93B may have a thickness T6. The thickness T5 and the thickness T6 may be the same or different. In some embodiments, the width W3 and the width W4 are in a range from about 10 nm to about 100 μm. In some embodiments, the thickness T5 and the thickness T6 are in a range from about 10 nm to about 100 μm.

FIGS. 21A and 21B show the protective rings 93 in the top integrated circuit die 50 as two concentric fragmented rings as an example. In some embodiments, the top integrated circuit die 50 has one fragmented ring as the protective ring 93. In some embodiments, the top integrated circuit die 50 has more than one protective ring 93, which may be one or more concentric fragmented rings, one or more concentric continuous rings, or a combination thereof. In some embodiments, the protective rings 93 in the top integrated circuit die 50 also have variations in structures as described with respect with to FIGS. 6C, 17, 18, and 20. FIG. 21C shows an embodiment in which the protective rings 93 in the top integrated circuit die 50 are three concentric fragmented rings and the protective ring 93 are rectangular frames with chamfered corners (e.g., octagonal frames). The protective ring(s) 93 in the bottom integrated circuit die 100 may also have same or similar structure and/or shapes as the protective rings 93 in the top integrated circuit die 50.

Embodiments may achieve advantages. The top integrated circuit dies 50 and the bottom integrated circuit die 100 may be formed with enlarged sizes without enlarging the sizes of the center regions 99 and the center region 121, which reduces the amount of the bottom encapsulant 128 and the top encapsulant 134 used, respectively. As a result, the risk of cracks in the bottom encapsulant 128 and the top encapsulant 134 may be reduced. The protective rings 93 and the protective ring 93 may be formed in the top integrated circuit dies 50 and the bottom integrated circuit die 100, respectively, which may reduce the risk of cracks in the center regions 99 and the center region 121 during the singulation processes, thereby improving the yield and reliability of the top integrated circuit dies 50 and the bottom integrated circuit die 100. Overall, the reliability of the integrated circuit package 300 is improved.

In an embodiment, a semiconductor structure includes an integrated circuit die including a substrate having an electrical device; an interconnect structure on the substrate, wherein the interconnect structure includes dielectric layers and conductive features, wherein the conductive features are electrically coupled to the electrical device; a seal ring in the dielectric layers of the interconnect structure, wherein the seal ring encircles the electrical device in a top down view; and a protective ring at least partially embedded in the substrate, wherein the protective ring encircles the seal ring in a top down view, and wherein the protective ring includes a material different from a material of the substrate; and an encapsulant encircling the integrated circuit die in the top down view. In an embodiment, the protective ring is electrically isolated from the electrical device. In an embodiment, the protective ring extends through the dielectric layers of the interconnect structure, and wherein the material of the protective ring is different from materials of the dielectric layers. In an embodiment, the protective ring is completely embedded in the substrate. In an embodiment, the protective ring is between an outer edge of the seal ring and a first edge of the integrated circuit die in the top down view, wherein the first edge of the integrated circuit die is a closest edge of the integrated circuit die to the outer edge of the seal ring, and wherein the first edge of the integrated circuit die includes a chamfered corner of the integrated circuit die. In an embodiment, the protective ring is between an outer edge of the seal ring and a first edge of the integrated circuit die in the top down view, wherein the first edge of the integrated circuit die is a closest edge of the integrated circuit die to the outer edge of the seal ring, wherein the outer edge of the seal ring is spaced apart from the first edge of the integrated circuit die by a first distance, wherein the integrated circuit die has a first width, and wherein a ratio of the first distance to the first width is in a range from 0.004 to 0.008.

In an embodiment, a semiconductor structure includes a first integrated circuit die, wherein the first integrated circuit die includes a substrate having a device region, wherein the substrate includes a first material; an interconnect structure on the substrate; a seal ring in the interconnect structure; and a protective feature in the interconnect structure and the substrate, wherein the protective feature includes a second material different from the first material, wherein the seal ring is between the protective feature and the device region. In an embodiment, the second material is a dielectric material. In an embodiment, the second material is a conductive material. In an embodiment, the semiconductor structure further includes an encapsulant, wherein the encapsulant includes a polymer. In an embodiment, first integrated circuit die is one of one or more integrated circuit dies, wherein the one or more integrated circuit dies have a first total area in a top down view, wherein the encapsulant has a second total area in the top down view, and wherein a ratio of the first total area to the second total area is in a range from 2 to 3. In an embodiment, the protective feature includes a first portion, wherein a surface of the first portion is level with a surface of the substrate. In an embodiment, the protective feature is one or more concentric continuous rings encircling the seal ring in a top down view. In an embodiment, the protective feature is one or more concentric fragmented rings encircling the seal ring in a top down view.

In an embodiment, a method of forming a semiconductor structure includes forming a first portion of a protective structure in a semiconductor wafer, wherein the semiconductor wafer includes a first material, wherein the first portion of the protective structure includes a second material different from the first material; forming an interconnect structure on the semiconductor wafer, wherein the interconnect structure includes a seal ring in the interconnect structure; and performing a singulation process to form an integrated circuit die by separating the semiconductor wafer, wherein the integrated circuit die includes the protective structure, the seal ring, and the interconnect structure, and wherein the protective structure is between the seal ring and an edge of the integrated circuit die in a top down view. In an embodiment, the method further includes forming a second portion of the protective structure, wherein the second portion of the protective structure extends through the interconnect structure. In an embodiment, the second portion of the protective structure includes the second material, wherein the seal ring includes a third material, and wherein the second material is a same material as the third material. In an embodiment, protective structure has a frame shape in the top down view, wherein the seal ring has a frame shape in the top down view, and wherein the protective structure encloses the seal ring in the top down view. In an embodiment, the first portion of the protective structure is disposed below a surface of the semiconductor wafer, and wherein the seal ring is in contact with the surface of the semiconductor wafer. In an embodiment, the method further includes forming an encapsulant around the integrated circuit die, wherein a coefficient of thermal expansion of the encapsulant is larger than a coefficient of thermal expansion of the integrated circuit die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
an integrated circuit die comprising:
a substrate having an electrical device;
an interconnect structure on the substrate, wherein the interconnect structure comprises dielectric layers and conductive features, wherein the conductive features are electrically coupled to the electrical device;
a seal ring in the dielectric layers of the interconnect structure, wherein the seal ring encircles the electrical device in a top down view; and
a protective ring at least partially embedded in the substrate, wherein the protective ring encircles the seal ring in a top down view, and wherein the protective ring comprises a material different from a material of the substrate; and
an encapsulant encircling the integrated circuit die in the top down view.

2. The semiconductor structure of claim 1, wherein the protective ring is electrically isolated from the electrical device.

3. The semiconductor structure of claim 1, wherein the protective ring extends through the dielectric layers of the interconnect structure, and wherein the material of the protective ring is different from materials of the dielectric layers.

4. The semiconductor structure of claim 1, wherein the protective ring is completely embedded in the substrate.

5. The semiconductor structure of claim 1, wherein the protective ring is between an outer edge of the seal ring and a first edge of the integrated circuit die in the top down view, wherein the first edge of the integrated circuit die is a closest edge of the integrated circuit die to the outer edge of the seal ring, and wherein the first edge of the integrated circuit die comprises a chamfered corner of the integrated circuit die.

6. The semiconductor structure of claim 1, wherein the protective ring is between an outer edge of the seal ring and a first edge of the integrated circuit die in the top down view, wherein the first edge of the integrated circuit die is a closest edge of the integrated circuit die to the outer edge of the seal ring, wherein the outer edge of the seal ring is spaced apart from the first edge of the integrated circuit die by a first distance, wherein the integrated circuit die has a first width, and wherein a ratio of the first distance to the first width is in a range from 0.004 to 0.008.

7. A semiconductor structure, comprising:
a first integrated circuit die, wherein the first integrated circuit die comprises:
a substrate having a device region, wherein the substrate comprises a first material;
an interconnect structure on the substrate;
a seal ring in the interconnect structure; and
a protective feature in the interconnect structure and the substrate, wherein the protective feature comprises a second material different from the first material, wherein the seal ring is between the protective feature and the device region.

8. The semiconductor structure of claim 7, wherein the second material is a dielectric material.

9. The semiconductor structure of claim 7, wherein the second material is a conductive material.

10. The semiconductor structure of claim 7, further comprising an encapsulant, wherein the encapsulant comprises a polymer.

11. The semiconductor structure of claim 10, wherein first integrated circuit die is one of one or more integrated circuit dies, wherein the one or more integrated circuit dies have a first total area in a top down view, wherein the encapsulant has a second total area in the top down view, and wherein a ratio of the first total area to the second total area is in a range from 2 to 3.

12. The semiconductor structure of claim 7, wherein the protective feature comprises a first portion, wherein a surface of the first portion is level with a surface of the substrate.

13. The semiconductor structure of claim 7, wherein the protective feature is one or more concentric continuous rings encircling the seal ring in a top down view.

14. The semiconductor structure of claim 7, wherein the protective feature is one or more concentric fragmented rings encircling the seal ring in a top down view.

15. A method of forming a semiconductor structure, the method comprising:
forming a first portion of a protective structure in a semiconductor wafer, wherein the semiconductor wafer comprises a first material, wherein the first portion of the protective structure comprises a second material different from the first material;
forming an interconnect structure on the semiconductor wafer, wherein the interconnect structure comprises a seal ring in the interconnect structure; and
performing a singulation process to form an integrated circuit die by separating the semiconductor wafer, wherein the integrated circuit die comprises the protective structure, the seal ring, and the interconnect structure, and wherein the protective structure is between the seal ring and an edge of the integrated circuit die in a top down view.

16. The method of claim 15, further comprising forming a second portion of the protective structure, wherein the second portion of the protective structure extends through the interconnect structure.

17. The method of claim 16, wherein the second portion of the protective structure comprises the second material, wherein the seal ring comprises a third material, and wherein the second material is a same material as the third material.

18. The method of claim 15, wherein protective structure has a frame shape in the top down view, wherein the seal ring has a frame shape in the top down view, and wherein the protective structure encloses the seal ring in the top down view.

19. The method of claim 15, wherein the first portion of the protective structure is disposed below a surface of the semiconductor wafer, and wherein the seal ring is in contact with the surface of the semiconductor wafer.

20. The method of claim 15, further comprising forming an encapsulant around the integrated circuit die, wherein a coefficient of thermal expansion of the encapsulant is larger than a coefficient of thermal expansion of the integrated circuit die.
